(19) United States
(12) Patent Application Publication
(10) Pub. No.: US 2022/0236428 A1
(43) Pub. Date: Jul. 28, 2022

(54) X-RAY DETECTION SUBSTRATE, X-RAY DETECTOR, AND X-RAY DETECTION SYSTEM

(71) Applicant: BOE Technology Group Co., Ltd., Beijing (CN)

(72) Inventor: Zeyuan LI, Beijing (CN)

(21) Appl. No.: 17/476,376

(22) Filed: Sep. 15, 2021

(30) Foreign Application Priority Data
Jan. 22, 2021 (CN) 202110087135.6

(51) Int. Cl. G01T 1/24; H01L 27/146; H01L 31/115

(52) U.S. Cl. CPC G01T 1/241; H01L 31/115; H01L 27/14676

(57) ABSTRACT

An X-ray detection substrate is provided. The X-ray detection substrate includes: a base, including at least a detection function region; a drive circuit layer, including a plurality of detection pixel circuits disposed in the detection function region; a first electrode layer, disposed in the detection function region and including a plurality of first electrodes that are disconnected from each other and arranged in an array, wherein each first electrode is correspondingly connected to one detection pixel circuit; a conversion material layer, disposed in the detection function region and covering the first electrode layer, wherein at least one surface, parallel to a thickness direction of the base, of the conversion material layer is an X-ray receiving surface; and a second electrode layer, disposed in the detection function region and covering the conversion material layer.

### CROSS-REFERENCE TO RELATED APPLICATION

This application claims priority to Chinese Patent Application 202110087135.6, filed on Jan. 22, 2021, and entitled “X-RAY DETECTION SUBSTRATE AND X-RAY DETECTOR”, the disclosure of which is incorporated herein by reference in its entirety.

### TECHNICAL FIELD

The present disclosure relates to the field of detection technologies, and in particular, to an X-ray detection substrate, an X-ray detector, and an X-ray detection system.

### BACKGROUND

The X-ray inspection technology is widely used in industrial non-destructive testing, container scanning, circuit board inspection, medical treatment, security, industries and the like, and has a broad application prospect.

### SUMMARY

In a first aspect of the present disclosure, an X-ray detection substrate is provided. The X-ray detection substrate includes: a base, including at least a detection function region; a drive circuit layer, wherein the drive circuit layer is formed on the base and comprises a plurality of detection pixel circuits disposed in the detection function region; a first electrode layer, wherein the first electrode layer is formed on a side of the drive circuit layer away from the base and disposed in the detection function region, and the first electrode layer comprises a plurality of first electrodes disconnected from each other, each first electrode being correspondingly connected to one detection pixel circuit and being configured to load a first reference voltage; a conversion material layer, wherein the conversion material layer is disposed in the detection function region and covers the first electrode layer, the conversion material layer is configured to convert received X-rays into carriers, and at least one surface, parallel to a thickness direction of the base, of the conversion material layer is an X-ray receiving surface; and a second electrode layer, wherein the second electrode layer is disposed in the detection function region and covers the conversion material layer, and the second electrode layer is configured to load a second reference voltage.

In some embodiments, the detection pixel circuit includes a transistor and a storage capacitor, wherein the storage capacitor is connected to the first electrode layer through the transistor, the first electrode layer is configured to collect the carriers and transfer a charge to the storage capacitor, and the storage capacitor is configured to store the charge; and the transistor is further connected to a signal reading circuit, and is configured to, in response to being turned on, transmit a current signal to the signal reading circuit based on the charge stored in the storage capacitor.

In some embodiments, the X-ray detection substrate further includes the signal reading circuit, wherein the signal reading circuit is configured to generate image data based on current signals transmitted by the plurality of detection pixel circuits.

In some embodiments, the base further includes a light collimation region, wherein the light collimation region is on a side of the detection function region close to the X-ray receiving surface; and the X-ray detection substrate further includes a light collimation layer, wherein the light collimation layer is disposed in the light collimation region.

In some embodiments, the light collimation layer includes at least an X-ray absorption layer, wherein in a direction perpendicular to the X-ray receiving surface, the X-ray absorption layer covers a partial region of the X-ray receiving surface, or the X-ray absorption layer does not overlap with the X-ray receiving surface.

In some embodiments, the X-ray receiving surface includes a first region and a second region on a side of the first region away from the base, wherein an orthographic projection of the X-ray absorption layer on the X-ray receiving surface covers the first region of the X-ray receiving surface, and does not overlap with the second region of the X-ray receiving surface.

In some embodiments, a ratio of a dimension of the first region in the thickness direction of the base to a dimension of the X-ray receiving surface in the thickness direction of the base is less than or equal to 0.1.

In some embodiments, a side of the X-ray absorption layer away from the base is closer to the base than a side of the first electrode layer away from the base; or the side of the X-ray absorption layer away from the base is flush with the side of the first electrode layer away from the base.

In some embodiments, the plurality of first electrodes are arranged in an array along a row direction and a column direction, the row direction is perpendicular to the column direction, and the row direction is perpendicular to the X-ray receiving surface; wherein in a direction going away from the X-ray receiving surface, lengths of the first electrodes in each row of first electrodes sequentially increase; or in the direction going away from the X-ray receiving surface, the lengths of the first electrodes in each row of first electrodes are equal; wherein the length of the first electrode is a dimension of the first electrode in the row direction.

In some embodiments, widths of the first electrodes are equal, wherein the width of the first electrode is a dimension of the first electrode in the column direction.

In some embodiments, a material of the conversion material layer is amorphous selenium, mercury iodide, lead iodide, bismuth iodide, or cadmium zinc telluride.

In some embodiments, the detection pixel circuit comprises a transistor and a storage capacitor, wherein the transistor comprises a gate and an active layer that are opposite to each other in the thickness direction of the base, and a source and a drain that are connected to two ends of the active layer, respectively, the drain being connected to the first electrode; and the storage capacitor comprises a first plate and a second plate that are opposite to each other in the thickness direction of the base, wherein the first plate and the gate are disposed in a same layer and disconnected from each other, the second plate is disposed in a same layer with the source and the drain, and the second plate is connected to the drain; and the drive circuit layer further comprises a gate line, a data line, and a common signal line that are formed on the base and disposed in the detection function region, wherein the gate line and the gate are disposed in a same layer and connected to each other; the data line and the source are disposed in a same layer and connected to each other; the common signal line and the first plate are disposed in a same layer and connected to each other.

In some embodiments, a material of the base includes glass or polyimide

In a second aspect of the present disclosure, an X-ray detector is provided. The X-ray detector includes a plurality of X-ray detection substrates, wherein the X-ray detection substrate is any of the X-ray detection substrates described above, and the plurality of X-ray detection substrates are stacked in a thickness direction of a base.

In some embodiments, the X-ray receiving surfaces of the X-ray detection substrates are flush with each other.

In some embodiments, in any two adjacent X-ray detection substrates, the base of one X-ray detection substrate is adjacent to the second electrode layer of the other X-ray detection substrate.

In some embodiments, the plurality of X-ray detection substrates are divided into a plurality of groups, each group including two of the X-ray detection substrates, and in each group, the second electrode layer of one X-ray detection substrate is adjacent to the second electrode layer of the other X-ray detection substrate.

In some embodiments, a distance between the conversion material layers of any two adjacent X-ray detection substrates is equal.

In a third aspect of the present disclosure, an X-ray detection system is provided. The X-ray detection system includes an X-ray source and the X-ray detector provided in the foregoing aspect, wherein the X-ray source is configured to emit X-rays, and the X-rays are incident on the conversion material layer in the X-ray detector after passing through a detection object.

### BRIEF DESCRIPTION OF THE DRAWINGS

The accompanying drawings, which are incorporated in and constitute a part of this specification, illustrate the embodiments of the present disclosure and serve to explain the principles of the present disclosure together with the description. Apparently, the accompanying drawings in the following description show merely some embodiments of the present disclosure, and persons of ordinary skill in the art may still derive other drawings from these accompanying drawings without creative efforts.

FIG. 1 to FIG. 3 are schematic structural diagrams of an X-ray detection substrate according to different embodiments of the present disclosure;

FIG. 4 is a schematic diagram of an energy spectrum detection principle of an X-ray detection substrate according to an embodiment of the present disclosure;

FIG. 5 is a planar schematic diagram of a partial structure of an X-ray detection substrate according to an embodiment of the present disclosure;

FIG. 6 is a schematic cross-sectional view. taken along direction A-A, of the structure in FIG.

FIG. 7 and FIG. 8 are planar schematic diagrams of a partial structure of an X-ray detection substrate according to different embodiments of the present disclosure;

FIG. 9 and FIG. 10 are schematic structural diagrams of an X-ray detector according to different embodiments of the present disclosure; and

FIG. 11 is a schematic structural diagram of X-ray detection system according to an embodiment of the present disclosure.

### DETAILED DESCRIPTION

The technical solutions of the present disclosure are further described below through embodiments in combination with the accompanying drawings. In the specification, the same or similar reference numerals indicate the same or similar parts. The following descriptions of the embodiments of the present disclosure with reference to the accompanying drawings are intended to explain the general conception of the present disclosure, but should not be construed as a limitation on the present disclosure.

In addition, in the detailed descriptions below, for ease of illustration, many specific details are illustrated to provide a comprehensive understanding of the embodiments of the present disclosure. However, it is obvious that one or more embodiments can also be implemented without the specific details.

Unless otherwise defined, the technical and scientific terms used herein have the general meaning as usually understood by those skilled in the art to which the present disclosure pertains. The “first”, “second” and similar words used in the present disclosure do not denote any order, quantity or importance, but are merely intended to distinguish between different constituents.

“Comprising”, “including”, “having” and similar words used in the present disclosure mean that an element or article appearing before the term includes elements or articles and their equivalent elements appearing after the term, without excluding any other elements or articles.

An X-ray flat panel detector in the related art cannot obtain information of X-rays of different energies, which limits the image resolution and application scope.

As shown in FIG. 1 to FIG. 3, the embodiments of the present disclosure provide an X-ray detection substrate 10. The X-ray detection substrate 10 includes a base 101, a drive circuit layer 102, a first electrode layer, a conversion material layer 104, and a second electrode layer 105.

The base 101 may include at least a detection function region 101a. The drive circuit layer 102 may be formed on the base 101, and the drive circuit layer 102 may include a plurality of detection pixel circuits disposed in the detection function region 101a. The first electrode layer may be formed on a side of the drive circuit layer 102 away from the base 101, and is disposed in the detection function region 101a. The first electrode layer may be a patterned structure. That is, the first electrode layer may include a plurality of first electrodes 103 disconnected from each other. The plurality of first electrodes 103 are in one-to-one correspondence with the plurality of detection pixel circuits. Each first electrode 103 is correspondingly connected to one detection pixel circuit and is configured to load a first reference voltage to the conversion material layer 104.

The conversion material layer 104 may be disposed in the detection function region 101a and covers the first electrode layer. That is, the orthographic projection of the first electrode layer on the base 101 is within the orthographic projection of the conversion material layer 104 on the base 101.

The second electrode layer 105 may be disposed in the detection function region 101a and covers the conversion material layer 104. That is, the orthographic projection of the conversion material layer 104 on the base 101 is within the orthographic projection of the second electrode layer 105 on the base 101. The second electrode layer 105 is configured to load a second reference voltage to the conversion material layer 104. Here, the second reference voltage is a high voltage relative to the first reference voltage, and therefore an electrical field can be formed on two sides of the conversion material layer 104.

In the embodiments of the present disclosure, the conversion material layer 104 is configured to convert received X-rays into carriers. Electron-hole pairs in the carriers drift towards the first electrode layer and the second electrode layer 105 respectively under the effect of the electrical field, and are collected by the first electrode layer and the second electrode layer 105, to generate current signals. Holes can move towards the second electrode layer 105 under the effect of the electrical field. Electrons can move towards the first electrode layer under the effect of the electrical field. Thus, the first electrode 103 can collect the electrons and transfer the charge to the detection pixel circuit. The detection pixel circuit can store the charge, and transmit a current signal to a connected signal reading circuit based on the stored charge. The signal reading circuit can generate image data, such as an energy spectrum of an image, based on the received current signal.

It is to be understood that the second reference voltage may be much higher than the first reference voltage. Therefore, even if the first electrode 103 collects electrons in the conversion material layer 104, the voltage loaded by the first electrode 103 to the conversion material layer 104 is still a low voltage compared with the second reference voltage. That is, the impact of the electrons collected by the first electrode 103 on the first reference voltage may be ignored.

It is further to be understood that in the embodiments of the present disclosure, the conversion material layer 104 and the second electrode layer 105 disposed in the detection function region 101a may be full-layer structures without being patterned. However, the embodiments of the present disclosure are not limited thereto. The structures of the conversion material layer 104 and the second electrode layer 105 may also be adjusted according to actual situations, as long as the X-ray detection substrate 10 can implement the detection function. The first electrodes 103 in the first electrode layer are disconnected from each other, and each first electrode 103 is correspondingly connected to one detection pixel circuit, such that each first electrode 103 is equivalent to a detection point.

In the embodiments of the present disclosure, at least one surface, which is parallel to the thickness direction Z of the base 101, of the conversion material layer 104 may be an X-ray receiving surface 104a. When a plurality of types of X-rays of different energies, for example low-energy X-rays and high-energy X-rays, are simultaneously incident on the X-ray receiving surface 104a parallel to the thickness direction Z of the base 101, electrons obtained through excitation under the interaction between the X-rays of different energies and the conversion material layer 104 have different generation probability distributions at different depths of the conversion material layer 104. That is, if the number of electrons (or the probability of generating electrons) excited by the X-rays of each energy at different depths of the conversion material layer 104 is counted to obtain a statistical curve, the statistical curves of X-rays of different energies are different. The depth direction of the conversion material layer 104 is perpendicular to the thickness direction Z of the base 101.

Therefore, by applying the electric field to the conversion material layer 104 by the first electrode layer and the second electrode layer 105 to collect electrons generated at different depths of the conversion material layer 104, the incident intensity of the X-rays of the two energies can be derived from the distribution of the number of generated electrons in the depth direction, thereby obtaining information of the energy spectrum and energy. In other words, the X-ray detection substrate 10 provided in the embodiments of the present disclosure can implement energy spectrum detection, to obtain energy spectrum information of the image, which facilitates distinguishment of detection objects such as soft tissues, and helps diagnosis in the medical field.

The measured values shown in FIG. 4 may be the energy spectrum information detected by the X-ray detection substrate of the present disclosure. Information of the low-energy X-ray and information of the high-energy X-ray received by the X-ray detection substrate as shown in FIG. 4 can be derived from the measured values. In FIG. 4, the horizontal axis indicates the incident depth of the X-rays in the conversion material layer 104, or may refer to an arrangement position of the first electrode 103 (or the corresponding detection pixel circuit) in the row direction M, and the vertical axis represents the number of electrons collected by the first electrode 103 in the X-ray detection substrate. The number of electrons reflects the intensity of the X-ray.

In addition, in the embodiments of the present disclosure, the surface, which is perpendicular to the thickness direction Z of the base 101, of the conversion material layer 104 may also be an X-ray receiving surface. When the surface, perpendicular to the thickness direction Z of the base 101, of the conversion material layer 104 is used as the X-ray receiving surface, the X-ray detection substrate 10 may also be used as a conventional flat panel detector. It should be understood that the conventional flat panel detector mentioned herein refers to an X-ray detector without an energy spectrum detection function. It should be noted that the X-ray receiving surface 104a mentioned below is mainly a surface parallel to the thickness direction Z of the base 101.

Based on the content above, the X-ray detection substrate 10 of the embodiments of the present disclosure may be used as both a conventional flat panel detector and an energy spectrum detector, which greatly expands the application scope.

In addition, when the X-ray detection substrate 10 of the embodiments of the present disclosure is used as an energy spectrum detector, compared with the conventional energy spectrum detector on the market which is made from single crystals, gemstone, or an avalanche photodiode (APD) which are incompatible with a glass-based process, the X-ray detection substrate 10 of the embodiments of the present disclosure may be manufactured through a glass-based process, which effectively reduces the manufacturing cost of the detector components.

It should be noted that the glass-based process mentioned in the embodiments of the present disclosure is to use glass as the base 101, or use a polyimide (PI) layer easily grown on glass as the base 101. In other words, in the X-ray detection substrate 10 of the embodiments of the present disclosure, the material of the base 101 may be glass. Functional film layers in the X-ray detection substrate 10 (for example, the aforementioned drive circuit layer 102, the first electrode layer, the conversion material layer 104 and the second electrode layer 105) may be formed directly on the glass-based base. The base 101 is a part of the X-ray detection substrate 10. However, the embodiments of the present disclosure are not limited thereto, and the material of base 101 may also be polyimide (PI). When the material of the base 101 is PI, the X-ray detection substrate 10 can be manufactured in the following manner: a PI material layer first grows on the glass base, and the PI material layer is the base 101 of the X-ray detection substrate 10. Then, other film layers required for the X-ray detection substrate 10 are formed on the base 101, for example, the aforementioned drive circuit layer 102, the first electrode layer, the conversion material layer 104, and the second electrode layer 105. Afterwards, the base 101 is stripped off from the glass base to form the entire X-ray detection substrate 10.

In the embodiments of the present disclosure, the detection pixel circuit may include a transistor and a storage capacitor. The storage capacitor is connected to the first electrode layer through the transistor. The first electrode layer is configured to collect carriers formed in the conversion material layer 104 and transfer a charge to the storage capacitor. The storage capacitor is configured to store the charge.

The transistor is further connected to a signal reading circuit, and is configured to, when being turned on, transmit a current signal to the signal reading circuit based on the charge stored in the storage capacitor.

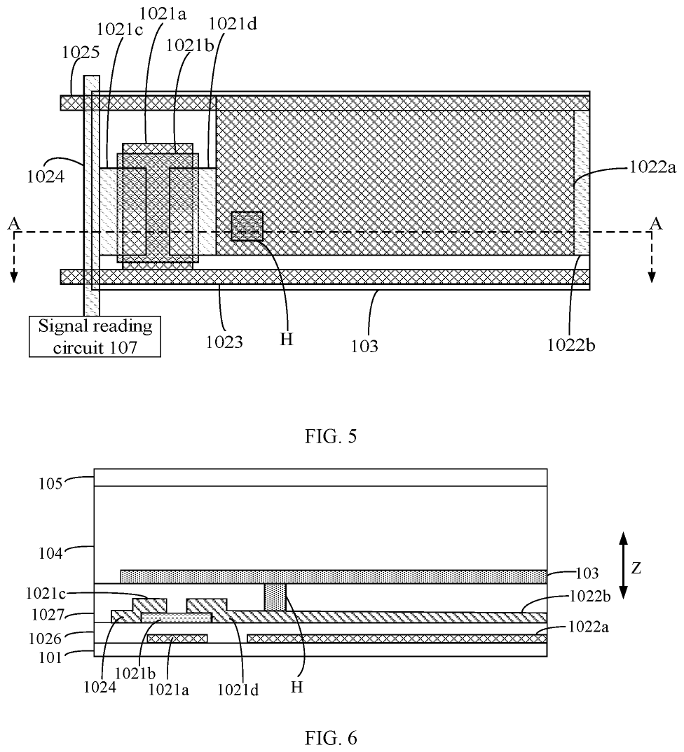

With reference to FIG. 5 and FIG. 6, the transistor in the detection pixel circuit is a thin film transistor (TFT). The transistor includes a gate 1021a and an active layer 1021b that are opposite to each other in the thickness direction Z of the base 101, and a source 1021c and a drain 1021d that are connected to two ends of the active layer 1021b, respectively.

For example, the transistor may be a bottom gate type transistor, that is, the gate 1021a is disposed on a side of the active layer 1021b close to the base 101. The orthographic projection of the active layer 1021b on the base 101 may overlap with the orthographic projection of the gate 1021a on the base 101. The material of the gate 1021a may be copper (Cu), silver (Ag), aluminum (Al), molybdenum (Mo), chromium (Cr), titanium (Ti) or other metals or alloys, to shield light for the active layer 1021b so as to ensure the property of the transistor. However, the embodiments of the present disclosure are not limited thereto, and the transistor may also be a top gate type transistor, that is, the gate 1021a is disposed on a side of the active layer 1021b away from the base 101, which depends on actual situations. The active layer 1021b may include amorphous silicon (a-Si), indium gallium zinc oxide (IGZO), or low temperature polycrystalline silicon (LTPS). The source 1021c and the drain 1021d are disposed in the same layer, and the source 1021c and drain 1021d may be of sandwich structures. For example, each of the source 1021c and drain 1021d may be formed by a Ti (titanium) layer, an Al (aluminum) layer, and a Ti (titanium) layer which are stacked sequentially. Since Al is prone to oxidation, the design of the Ti/Al/Ti sandwich structure can add Ti on and below Al, to effectively prevent Al from oxidation.

With reference to FIG. 5 and FIG. 6, the storage capacitor may include a first plate 1022a and a second plate 1022b that are opposite to each other in the thickness direction Z of the base 101. That is, the orthographic projection of the first plate 1022a on the base 101 overlaps with the orthographic projection of the second plate 1022b on the base 101. The first plate 1022a and the gate 1021a are disposed in the same layer, and the second plate 1022b is disposed in the same layer as the source 1021c and the drain 1021d.

It should be understood that in the present disclosure, “same layer” refers to a layer structure formed in the following manner: forming, through the same film formation process, film layers for forming specific patterns, and then forming the layer structure through a one-time patterning process with the same mask. That is, a one-time patterning process corresponds to one mask (which is also referred to as a photomask). For different specific patterns, the one-time patterning process may include a plurality of times of exposure, development or etching processes, and the specific patterns in the formed layer structure may be continuous or discontinuous, and these specific patterns may be at different heights or have different thicknesses, so as to simplify the manufacturing process, save the manufacturing costs and increase productivity.

In the embodiments of the present disclosure, the first plate 1022a of the storage capacitor is disconnected from the gate 1021a of the transistor. The second plate 1022b of the storage capacitor is connected to the drain 1021d of the transistor, and the drain 1021d of the transistor is further connected to the first electrode 103.

It is to be understood that the detection pixel circuit not only includes the aforementioned transistor and storage capacitor, etc. As shown in FIG. 6, when the transistor is a bottom gate type transistor, the detection pixel circuit may further include a gate insulating layer 1026 disposed between the active layer 1021b and the gate 1021a and between the first plate 1022a and the second plate 1022b, and further include an interlayer dielectric layer 1027 disposed between the drain 1021d and the first electrode layer. Based on this, as shown in FIG. 5 and FIG. 6, the first electrode 103 may be connected to the drain 1021d of the transistor through a via hole structure H that penetrates through the interlayer dielectric layer 1027.

It should be noted that the gate insulating layer 1026 and the interlayer dielectric layer 1027 are set as a whole layer in the entire drive circuit layer 102. The gate insulating layer 1026 and the interlayer dielectric layer 1027 may be made of inorganic materials such as silicon oxide, silicon nitride or silicon oxynitride.

In addition, as shown in FIG. 5 and FIG. 6, the drive circuit layer 102 may further include a gate line 1023, a data line 1024, and a common signal line 1025 formed on the base 101 and disposed in the detection function region 101a. The gate line 1023 and the gate 1021a of the transistor are disposed in the same layer and connected to each other. The data line 1024 and the source 1021c are disposed in the same layer and connected to each other. The common signal line 1025 and the first plate 1022a are disposed in the same layer and connected to each other.

Referring to FIG. 5, the data line 1024 may further be connected to the signal reading circuit 107. After the gate line 1023 controls the source 1021c and the drain 1021d of the transistor to be conducted, the transistor may transmit a current signal to the data line 1024 based on the charge stored in the storage capacitor. Then, the data line 1024 may transmit the current signal to the signal reading circuit 107.

Optionally, the X-ray detection substrate provided in the embodiments of the present disclosure may further include the signal reading circuit 107. The signal reading circuit 107 is configured to generate image data, for example an energy spectrum of an image, based on current signals transmitted by the plurality of detection pixel circuits. The signal reading circuit 107 may be disposed on a printed circuit board (PCB), or the signal reading circuit 107 may be disposed on a flexible circuit board, and the signal reading circuit 107 may be connected to the data line 1024 on the base 101 by a chip on film (COF) process.

In the embodiments of the present disclosure, as shown in FIG. 5, the orthographic projection of the first electrode 103 on the base 101 may completely cover orthographic projections of the transistor and the storage capacitor of the detection pixel circuit connected to the first electrode 103 on the base 101. However, the embodiments of the present disclosure are not limited thereto, and the orthographic projection of the first electrode 103 on the base 101 may also cover the orthographic projection of a partial structure of the transistor or a partial structure of the storage capacitor on the base 101, which depends on actual situations.

For example, the first electrode 103 may be made of a metal such as copper (Cu), silver (Ag), aluminum (Al), molybdenum (Mo), chromium (Cr), or titanium (Ti), or an alloy. When the first electrode 103 covers the active layer 1021b of the transistor, the first electrode 103 plays a light-shielding effect for the active layer 1021b to ensure the property of the transistor. However, the embodiments of the present disclosure are not limited thereto, and the first electrode 103 may also be made of other materials, such as indium tin oxide (ITO). Alternatively, the first electrode 103 may be a composite structure. For example, the first electrode 103 includes a light-shielding metal layer and a transparent metal oxide layer or the like disposed on a side of the light-shielding metal layer away from the base 101.

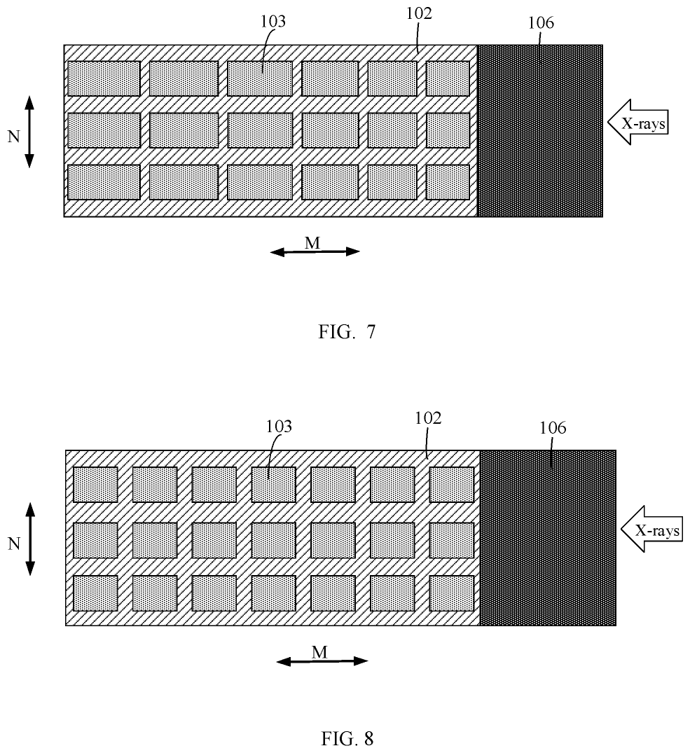

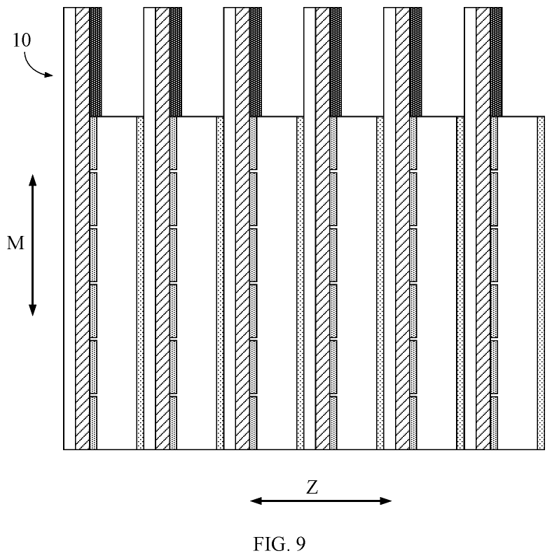

In the embodiments of the present disclosure, as shown in FIG. 7 and FIG. 8, the plurality of first electrodes 103 in the first electrode layer are arranged in an array along a row direction M and a column direction N. The row direction M and the column direction N are perpendicular to each other, and the row direction M is perpendicular to the X-ray receiving surface 104a. Low-energy X-rays are completely absorbed in an area near the X-ray receiving surface 104a, and high-energy X-rays are completely absorbed in an area far away from the X-ray receiving surface 104a. In other words, energies of X-rays completely absorbed by the conversion material layer 104 increase gradually in a direction going away from the X-ray receiving surface 104a.

To enable the parts of the conversion material layer 104 that correspond to the first electrodes 103 to completely absorb X-rays in corresponding energy bands, as shown in FIG. 7, the lengths of the first electrodes 103 in each row may increase sequentially in the direction going away from the X-ray receiving surface 104a. That is, the X-rays in different energy bands are completely absorbed in the range of different electrode lengths.

It should be noted that in the embodiments of the present disclosure, the design of the first electrodes 103 in the first electrode layer is not limited to the aforementioned case where the lengths of the first electrodes 103 increase sequentially in the direction going away from the X-ray receiving surface 104a. Alternatively, as shown in FIG. 8, the lengths of the first electrodes 103 in each row are equal in the direction going away from the X-ray receiving surface 104a, in order to reduce the design difficulty. However, the embodiments of the present disclosure are not limited thereto, and the lengths of the first electrodes 103 in each row may decrease sequentially in the direction going away from the X-ray receiving surface 104a.

In the embodiments of the present disclosure, the widths of the first electrodes 103 in the first electrode layer are equal. In addition, the thicknesses of the first electrodes 103 in the first electrode layer may be equal. However, the embodiments of the present disclosure are not limited thereto, and the first electrodes 103 may have unequal widths and thicknesses.

In addition, a spacing between two adjacent first electrodes 103 in the row direction M may be a fixed value, that is, the first electrodes 103 in each row may be uniformly spaced apart in the row direction M. A spacing between two adjacent first electrodes 103 in the column direction N may be a fixed value, that is, the first electrodes 103 in each column may be uniformly spaced apart in the column direction N. In this way, the design difficulty can be reduced. However, the embodiments of the present disclosure are not limited thereto.

It should be noted that the length of the first electrode 103 mentioned in the embodiments of the present disclosure is a dimension of the first electrode 103 in the row direction M, and the width of the first electrode 103 is a dimension of the first electrode 103 in the column direction N.

For example, the shape of each first electrode 103 in the first electrode layer may be a rectangle as shown in FIG. 7 and FIG. 8, to reduce the design difficulty. However, the shape of the first electrode 103 is not limited thereto, and may be other shapes, such as an oval or diamond shape.

It should be understood that the above descriptions of “row direction” and “column direction” are used only to distinguish between two different directions. In other possible embodiments, the row direction M may also be referred to as column direction M, and correspondingly, the column direction N may be referred to as row direction N.

In the embodiments of the present disclosure, the conversion material layer 104 may be a direct conversion material layer. The direct conversion material layer is configured to convert received X-rays into carriers directly. Compared with the scheme where the conversion material layer is an indirect conversion material layer, the direct conversion material layer in the present disclosure can directly convert X-rays into carriers. Therefore, the loss of X-ray energy can be reduced and the accuracy of energy spectrum detection can be improved. It should be understood that the indirect conversion material layer mentioned herein refers to a structure that first converts X-rays into visible light by using a fluorescent scintillator material, and then converts the visible light into carriers by using a photoelectric conversion material.

For example, the material of the direct conversion material layer may be amorphous selenium (a-Se), mercury iodide (HgI2), lead iodide (PbI2), bismuth iodide (Bi I2) or cadmium zinc telluride (CZT), etc. However, the material of the direct conversion material layer is not limited thereto, and may also be other materials that can convert X-rays into carriers.

The second electrode layer 105 may be a transparent electrode layer. For example, the material of the second electrode layer 105 may be a transparent metal oxide material such as ITO. In such a design, absorption of X-rays by the second electrode layer 105 can be reduced when the X-ray receiving surface 104a perpendicular to the thickness direction Z of the base 101 is used for detection. However, the embodiments of the present disclosure are not limited thereto, and the second electrode layer 105 may also be made of other metallic materials.

For example, in the embodiments of the present disclosure, when the base 101 is a glass base, the total thickness of the base 101 and the drive circuit layer 102 may range from 2 μm to 3 μm. For example, the total thickness may be 2 μm, 2.2 μm, 2.4 μm, 2.6 μm, 2.8 μm, 3 μm or the like. The thickness of each of the first electrode layer and the second electrode layer 105 may be less than or equal to 1 μm. For example, the thickness of each electrode layer may be 0.1 μm, 0.3 μm, 0.5 μm, 0.7 μm, 0.9 μm, 1 μm, or the like. The thickness of the conversion material layer 104 may range from 200 μm to 500 μm, for example, 200 μm, 250 μm, 300 μm, 350 μm, 400 μm, 450 μm, 500 μm, or the like.

It should be understood that the total thickness of the base 101 and the drive circuit layer 102, the thickness of the first electrode layer, the thickness of the second electrode layer 105, and the thickness of the conversion material layer 104 are not limited to the aforementioned range, which depends on actual situations.

In an embodiment of the present disclosure, as shown in FIG. 1 to FIG. 3, the base 101 may further include a light collimation region 101b. The light collimation region 101b is disposed on a side of the detection function region 101a close to the X-ray receiving surface 104a (that is, the X-ray receiving surface 104a parallel to the thickness direction Z of the base 101), and the light collimation region 101b is provided with a light collimation layer. That is, when X-rays are incident on the side of the X-ray receiving surface 104a parallel to the thickness direction Z of the base 101, the X-rays may first pass through the light collimation region 101b, and then enter the conversion material layer 104 in the detection function region 101a.

In the embodiments of the present disclosure, stray light in the X-rays can be absorbed or collimated by the light collimation layer, such that X-rays entering the conversion material layer 104 are substantially parallel to the base 101, thereby improving the accuracy of energy spectrum detection and the signal-to-noise ratio.

For example, with reference to FIG. 1 to FIG. 3, and FIG. 7 and FIG. 8, the light collimation layer may at least include an X-ray absorption layer 106. The light collimation layer in the embodiments of the present disclosure uses the X-ray absorption layer 106 to absorb stray light in the X-rays, such that the X-rays entering the conversion material layer 104 are substantially parallel to the base 101, thereby achieving the effect of light collimation. For example, the X-ray absorption layer 106 may be a lead layer, that is, the X-ray absorption layer 106 may be made of a lead material. However, the embodiments of the present disclosure are not limited thereto, and the X-ray absorption layer 106 may also be made of other materials, as long as the X-ray absorption layer 106 can absorb X-rays.

In the direction perpendicular to the X-ray receiving surface 104a (i.e., row direction M), the X-ray absorption layer 106 may cover a partial region of the X-ray receiving surface 104a. Alternatively, the X-ray absorption layer 106 does not overlap with the X-ray receiving surface 104a, that is, no area of the X-ray receiving surface 104a overlaps with the X-ray absorption layer 106.

It should be noted that the area, which does not overlap with the X-ray absorption layer 106, of the X-ray receiving surface 104a is the main area for receiving X-rays. If there is an area in the X-ray receiving surface 104a that overlaps with the X-ray absorption layer 106, the overlapping area can be construed as an area for absorbing stray light in the X-rays.

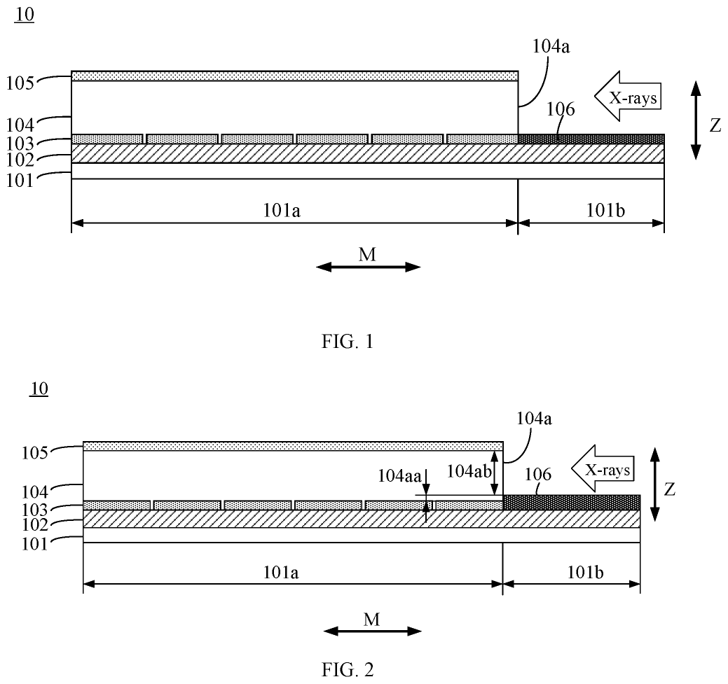

In an optional embodiment, as shown in FIG. 2, the X-ray receiving surface 104a has a first region 104aa and a second region 104ab disposed on a side of the first region 104aa away from the base 101. An orthographic projection of the X-ray absorption layer 106 on the X-ray receiving surface 104a covers the first region 104aa of the X-ray receiving surface 104a, and does not overlap with the second region 104ab of the X-ray receiving surface 104a. On the one hand, such a design facilitates manufacture of the X-ray absorption layer 106. On the other hand, while ensuring good performance of energy spectrum detection, such a design can effectively absorb stray light in the X-rays to improve the signal-to-noise ratio.

Optionally, the ratio of the dimension of the first region 104aa in the thickness direction Z of the base 101 to the dimension of the X-ray receiving surface 104a in the thickness direction Z of the base 101 is less than or equal to 0.1. For example, when the thickness of the conversion material layer 104 is 500 μm, that is, when the dimension of the X-ray receiving surface 104a in the thickness direction Z of the base 101 is 500 μm, in the X-ray receiving surface 104a, the dimension of the first region 104aa corresponding to the X-ray absorption layer 106 in the thickness direction Z of the base 101 is less than or equal to 50 μm. For example, the dimension of the first region 104aa in the thickness direction Z may be 10 μm, 20 μm, 30 μm, 40 μm or 50 μm, etc. While ensuring good performance of energy spectrum detection, such a design can effectively absorb stray light in the X-rays to improve the signal-to-noise ratio.

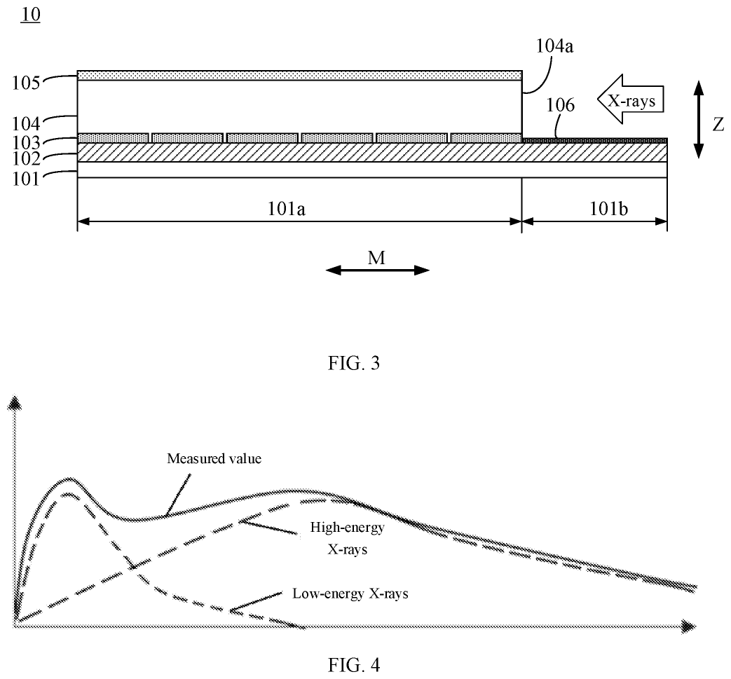

In another optional embodiment, as shown in FIG. 3, the side of the X-ray absorption layer 106 away from the base 101 is closer to the base 101 than the side of the first electrode layer away from the base 101. In other words, the side of the X-ray absorption layer 106 away from the base 101 is closer to the base 101 than the side of the conversion material layer 104 close to base 101. In this way, while the energy spectrum detection area is increased, stray light in the X-rays can be effectively absorbed, to improve the signal-to-noise ratio.

It should be noted that in this embodiment, the spacing between the X-ray absorption layer 106 and the conversion material layer 104 in the thickness direction Z of the base 101 should not be too large. That is, the spacing between the side of the X-ray absorption layer 106 away from the base 101 and the side of the conversion material layer 104 close to the base 101 should not be too large. For example, the spacing may be less than 10 μm, to ensure that the X-ray absorption layer 106 can effectively absorb stray light in the X-rays.

In yet another optional embodiment, as shown in FIG. 1, the side of the X-ray absorption layer 106 away from the base 101 is flush with the side of the first electrode layer away from the base 101. While ensuring good performance of energy spectrum detection, such a design can effectively absorb stray light in the X-rays to improve the signal-to-noise ratio.

In the embodiments of the present disclosure, the X-ray absorption layer 106 may be fabricated after the functional film layers in the detection function region 101a are fabricated. That is, after the second electrode layer 105 is fabricated, the X-ray absorption layer 106 may be formed by coating the light collimation region 101b with an X-ray absorption material, for example, a lead material.

It should be noted that the light collimation layer in the embodiments of the present disclosure is not limited to implement light collimation by absorbing stray light in the X-rays using the X-ray absorption layer 106 mentioned above. The light collimation layer in the embodiments of the present disclosure may also be a lens structure, which can collimate stray light in the X-rays to implement light collimation. That is, X-rays with a large deviation can be substantially parallel to the base 101 after passing through the lens structure, thereby improving the accuracy of energy spectrum detection and the signal-to-noise ratio.

It should also be noted that the light collimation region 101b of the base 101 may be provided with a peripheral circuit structure in addition to the light collimation layer.

In addition, in the embodiments of the present disclosure, after the second electrode layer 105 is fabricated, an encapsulation layer covering the second electrode layer 105 may be fabricated for encapsulation protection. However, the embodiments of the present disclosure are not limited thereto, and the encapsulation layer may not be provided.

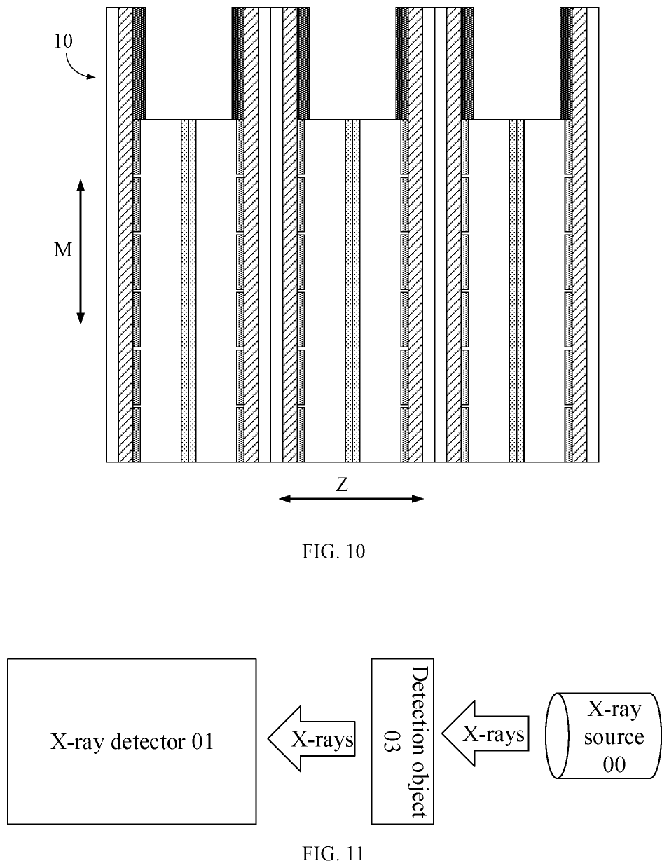

The embodiments of the present disclosure further provide an X-ray detector. As shown in FIG. 9 and FIG. 10, the X-ray detector includes a plurality of X-ray detection substrates 10. The X-ray detection substrate 10 is the structure described in any of the foregoing embodiments and is not described in detail again herein. The plurality of X-ray detection substrates 10 are stacked in the thickness direction Z of the base 101.

In the embodiments of the present disclosure, the X-ray detector including the plurality of X-ray detection substrates 10 may directly acquire a 2-dimensional energy spectrum resolution image. Compared with the scheme of acquiring 2-dimensional energy spectrum image data by scanning with one X-ray detection substrate 10, time can effectively be saved and thus the X-ray radiation duration can be reduced with the X-ray detector in the embodiments of the present disclosure. Correspondingly, when used in the medical field, the X-ray detector can effectively reduce the X-ray radiation to human body.

Optionally, the x-ray receiving surfaces 104a of the x-ray detection substrates 10 may be flush with each other, such that the difficulty of data processing can be effectively reduced in the process of directly acquiring a 2-dimensional energy spectrum resolution image.

In an optional embodiment, with reference to FIG. 2 and FIG. 9, in any two adjacent X-ray detection substrates 10, the base 101 of one X-ray detection substrates 10 is adjacent to the second electrode layer 105 of the other X-ray detection substrate 10, such that it's ensured the distance between the conversion material layers 104 of any two adjacent X-ray detection substrates 10 is a fixed value, that is, the conversion material layers 104 of the plurality of X-ray detection substrates 10 are uniformly spaced apart. In this way, the image data obtained by the X-ray detection substrates 10 can be more balanced, to ensure that the finally acquired energy spectrum image data can better reflect the actual situation. In addition, such a design can also reduce the design difficulty.

In another optional embodiment, with reference to FIG. 2 and FIG. 10, the plurality of X-ray detection substrates 10 are divided into a plurality of groups. Each group includes two X-ray detection substrates 10. In each group, the second electrode layer 105 of one X-ray detection substrate 10 is adjacent to the second electrode layer 105 of the other X-ray detection substrate 10.

Optionally, in this optional embodiment, the distance between the conversion material layers 104 of any two adjacent X-ray detection substrates 10 is also a fixed value, that is, the conversion material layers 104 of the plurality of X-ray detection substrates 10 are uniformly spaced apart. The fixed distance between the conversion material layers 104 of any two adjacent X-ray detection substrates 10 can be achieved by adjusting the thickness of structure, such as the base 101, the electrode layer or the encapsulation layer.

It should be noted that the X-ray detector provided in the embodiments of the present disclosure may further include other parts and components in addition to the aforementioned X-ray detection substrates 10. For example, the X-ray detector may further include a casing and a circuit board, etc., which may be supplemented accordingly by persons skilled in the art based on the specific usage requirements of the X-ray detector, and details are not described herein.

The embodiments of the present disclosure further provide an X-ray detection system. As shown in FIG. 11, the X-ray detection system includes an X-ray source 00 and an X-ray detector 01. The X-ray detector 01 is the structure described in any of the foregoing embodiments and is not described in detail herein.

With reference to FIG. 11, the X-ray source 00 is configured to emit X-rays. The X-rays may be incident on the conversion material layer 104 in the X-ray detector 01 after passing through a detection object 03. The X-ray detector may then generate image data, such as an energy spectrum of an image, based on the received X-rays.

Persons skilled in the art can easily think of other implementations of the present disclosure after considering the specification and practicing the content disclosed herein. The present disclosure is intended to cover any variations, purposes or applicable changes of the present disclosure. Such variations, purposes or applicable changes follow the general principle of the present disclosure and include common knowledge or conventional technical means in the technical field which is not disclosed in the present disclosure. The specification and embodiments are merely considered as illustrative, and the true scope and spirit of the present disclosure are pointed out by the appended claims.

What is claimed is:

1. An X-ray detection substrate, comprising:
a base, comprising at least a detection function region;
a drive circuit layer, wherein the drive circuit layer is formed on the base and comprises a plurality of detection pixel circuits disposed in the detection function region;
a first electrode layer, wherein the first electrode layer is formed on a side of the drive circuit layer away from the base and disposed in the detection function region, and the first electrode layer comprises a plurality of first electrodes disconnected from each other, each first electrode being correspondingly connected to one detection pixel circuit and being configured to load a first reference voltage;
a conversion material layer, wherein the conversion material layer is disposed in the detection function region and covers the first electrode layer, the conversion material layer is configured to convert received X-rays into carriers, and at least one surface, parallel to a thickness direction of the base, of the conversion material layer is an X-ray receiving surface; and
a second electrode layer, wherein the second electrode layer is disposed in the detection function region and covers the conversion material layer, and the second electrode layer is configured to load a second reference voltage.

2. The X-ray detection substrate according to claim 1, wherein the detection pixel circuit comprises a transistor and a storage capacitor, wherein
the storage capacitor is connected to the first electrode layer through the transistor, the first electrode layer is configured to collect the carriers and transfer a charge to the storage capacitor, and the storage capacitor is configured to store the charge; and
the transistor is further connected to a signal reading circuit, and is configured to, in response to being turned on, transmit a current signal to the signal reading circuit based on the charge stored in the storage capacitor.

3. The X-ray detection substrate according to claim 2, further comprising: the signal reading circuit, wherein the signal reading circuit is configured to generate image data based on current signals transmitted by the plurality of detection pixel circuits.

4. The X-ray detection substrate according to claim 1, wherein
the base further comprises a light collimation region, wherein the light collimation region is on a side of the detection function region close to the X-ray receiving surface; and
the X-ray detection substrate further comprises a light collimation layer, wherein the light collimation layer is disposed in the light collimation region.

5. The X-ray detection substrate according to claim 4, wherein the light collimation layer comprises at least an X-ray absorption layer, wherein
in a direction perpendicular to the X-ray receiving surface, the X-ray absorption layer satisfies one of the following conditions:
the X-ray absorption layer covers a partial region of the X-ray receiving surface; or
the X-ray absorption layer does not overlap with the X-ray receiving surface.

6. The X-ray detection substrate according to claim 5, wherein
the X-ray receiving surface comprises a first region and a second region on a side of the first region away from the base, wherein
an orthographic projection of the X-ray absorption layer on the X-ray receiving surface covers the first region of the X-ray receiving surface, and does not overlap with the second region of the X-ray receiving surface.

7. The X-ray detection substrate according to claim 6, wherein
a ratio of a dimension of the first region in the thickness direction of the base to a dimension of the X-ray receiving surface in the thickness direction of the base is less than or equal to 0.1.

8. The X-ray detection substrate according to claim 5, wherein the X-ray absorption layer satisfies one of the following conditions:
a side of the X-ray absorption layer away from the base is closer to the base than a side of the first electrode layer away from the base; or
the side of the X-ray absorption layer away from the base is flush with the side of the first electrode layer away from the base.

9. The X-ray detection substrate according to claim 1, wherein the plurality of first electrodes are arranged in an array along a row direction and a column direction, the row direction being perpendicular to the column direction, and the row direction being perpendicular to the X-ray receiving surface.

10. The X-ray detection substrate according to claim 9, wherein in a direction going away from the X-ray receiving surface, each row of first electrodes satisfies one of the following conditions:
lengths of the first electrodes in each row of first electrodes sequentially increase; or
the lengths of the first electrodes in each row of first electrodes are equal;
wherein the length of the first electrode is a dimension of the first electrode in the row direction.

11. The X-ray detection substrate according to claim 10, wherein widths of the first electrodes are equal, wherein the width of the first electrode is a dimension of the first electrode in the column direction.

12. The X-ray detection substrate according to claim 1, wherein a material of the conversion material layer is amorphous selenium, mercury iodide, lead iodide, bismuth iodide, or cadmium zinc telluride.

13. The X-ray detection substrate according to claim 1, wherein
the detection pixel circuit comprises a transistor and a storage capacitor, wherein the transistor comprises a gate and an active layer that are opposite to each other in the thickness direction of the base, and a source and a drain that are connected to two ends of the active layer respectively, the drain being connected to the first electrode; and the storage capacitor comprises a first plate and a second plate that are opposite to each other in the thickness direction of the base, the first plate and the gate being disposed in a same layer and disconnected from each other, the second plate being disposed in a same layer with the source and the drain, and the second plate being connected to the drain; and
the drive circuit layer further comprises a gate line, a data line, and a common signal line that are formed on the base and disposed in the detection function region, wherein the gate line and the gate are disposed in a same layer and connected to each other; the data line and the source are disposed in a same layer and connected to each other; and the common signal line and the first plate are disposed in a same layer and connected to each other.

14. The X-ray detection substrate according to claim 1, wherein a material of the base comprises glass or polyimide.

15. An X-ray detector, comprising a plurality of X-ray detection substrates that are stacked in a thickness direction of a base, wherein the X-ray detection substrate comprises:
the base, comprising at least a detection function region;
a drive circuit layer, wherein the drive circuit layer is formed on the base and comprises a plurality of detection pixel circuits disposed in the detection function region;
a first electrode layer, wherein the first electrode layer is formed on a side of the drive circuit layer away from the base and disposed in the detection function region, and the first electrode layer comprises a plurality of first electrodes disconnected from each other, each first electrode being correspondingly connected to one detection pixel circuit and being configured to load a first reference voltage;
a conversion material layer, wherein the conversion material layer is disposed in the detection function region and covers the first electrode layer, the conversion material layer is configured to convert received X-rays into carriers, and at least one surface, parallel to a thickness direction of the base, of the conversion material layer is an X-ray receiving surface; and
a second electrode layer, wherein the second electrode layer is disposed in the detection function region and covers the conversion material layer, and the second electrode layer is configured to load a second reference voltage.

16. The X-ray detector according to claim 15, wherein the X-ray receiving surfaces of the X-ray detection substrates are flush with each other.

17. The X-ray detector according to claim 15, wherein in any two adjacent X-ray detection substrates, the base of one X-ray detection substrate is adjacent to the second electrode layer of the other X-ray detection substrate.

18. The X-ray detector according to claim 15, wherein the plurality of X-ray detection substrates are divided into a plurality of groups, each group comprising two of the X-ray detection substrates, and in each group, the second electrode layer of one X-ray detection substrate is adjacent to the second electrode layer of the other X-ray detection substrate.

19. The X-ray detector according to claim 18, wherein a distance between the conversion material layers of any two adjacent X-ray detection substrates is equal.

20. An X-ray detection system, comprising: an X-ray source and an X-ray detector, wherein
the X-ray source is configured to emit X-rays; and
the X-ray detector comprises a plurality of X-ray detection substrates that are stacked in a thickness direction of a base, wherein the X-ray detection substrate comprises:
the base, comprising at least a detection function region;
a drive circuit layer, wherein the drive circuit layer is formed on the base and comprises a plurality of detection pixel circuits disposed in the detection function region;
a first electrode layer, wherein the first electrode layer is formed on a side of the drive circuit layer away from the base and disposed in the detection function region, and the first electrode layer comprises a plurality of first electrodes disconnected from each other, each first electrode being correspondingly connected to one detection pixel circuit and being configured to load a first reference voltage;
a conversion material layer, wherein the conversion material layer is disposed in the detection function region and covers the first electrode layer, the conversion material layer is configured to convert received X-rays into carriers, and at least one surface, parallel to a thickness direction of the base, of the conversion material layer is an X-ray receiving surface; and
a second electrode layer, wherein the second electrode layer is disposed in the detection function region and covers the conversion material layer, and the second electrode layer is configured to load a second reference voltage.
